(19) United States
(12) Patent Application Publication
(10) Pub. No.: US 2023/0369073 A1
(43) Pub. Date: Nov. 16, 2023

(54) THERMAL MANAGEMENT SYSTEMS AND DEVICES FOR CABINETS USED IN SEMICONDUCTOR FABRICATION PROCESSING

(71) Applicant: ASM IP Holding B.V., Almere (NL)

(72) Inventors: Ankit Kimtee, Phoenix, AZ (US); Sudhanshu Biyani, Tempe, AZ (US)

(21) Appl. No.: 18/195,422

(22) Filed: May 10, 2023

Related U.S. Application Data
(60) Provisional application No. 63/341,898, filed on May 13, 2022.

(51) Int. Cl. H01L 21/67

(52) U.S. Cl. CPC H01L 21/67017

(57) ABSTRACT

Cabinets used in semiconductor fabrication processes comprise a housing with an internal space having a storage vessel disposed therein that contains material used for semiconductor fabrication processing that is maintained at a set temperature. Thermal management systems and devices disclosed herein comprise a thermal insulating material that is disposed on the housing and that is positioned at one or more locations on the cabinet to reduce thermal transfer from an external thermal energy source external from and adjacent the cabinet to the internal space and the storage vessel. Use of the thermal insulating material functions to mitigate or eliminate the unwanted transfer of thermal energy from the external thermal energy source to the storage vessel inside of the cabinet to thereby not influence the set temperature of the storage vessel and its contents to thereby promote the effective and efficient use of the stored material during semiconductor fabrication.

### CROSS-REFERENCE TO RELATED APPLICATIONS

This application is a nonprovisional of, and claims priority to and the benefit of, U.S. Provisional Patent Application No. 63/341,898, filed May 13, 2022 and entitled “THERMAL MANAGEMENT SYSTEMS AND DEVICES FOR CABINETS USED IN SEMICONDUCTOR FABRICATION PROCESSING,” which is hereby incorporated by reference herein.

### FIELD

Systems and devices as disclosed herein relate to cabinets used in semiconductor fabrication processing and, more specifically, to systems and devices configured to provide an improved degree of thermal management of contents in such cabinets to optimize the temperature control of such contents as used in semiconductor fabrication processing.

### BACKGROUND

The use of different types of materials such as gases, liquids, solids during semiconductor fabrication processing is known. The gases or liquids may be in the form of acids or other types of chemicals used during different stages of the semiconductor fabrication processing, and may be provided in a heated or cooled condition for the purpose of effectively performing the particular semiconductor fabrication processing step. It is known that such gases, liquids, and solids are stored in one or more containers or vessels located within one or more enclosures in the form of cabinets. Such containers or vessels disposed in the cabinets may make use of appropriate heating or cooling devices for the purpose of maintaining the material in the containers or vessels at a desired controlled heated or cooled temperature for use. The placement position of the cabinets may vary, but are often near or adjacent other cabinets storing other materials therein, and may additionally be located near the reactor or reaction chamber used during semiconductor fabrication processing.

It is known that the cabinets comprising such material containers or vessels inside may be subject to certain external thermal sources or conditions, e.g., from other adjacent cabinets or from the reactor or reaction chamber or from other adjacent device or system, that influences the temperature inside of the cabinets. Such external thermal condition also influences the temperature of the material stored in the containers or vessels disposed inside the cabinets, which impairs the ability to maintain the material stored in such containers or vessels at a desired controlled or set temperature.

It is, therefore, desired that systems and devices be configured to mitigate or prevent the influence of external thermal conditions on cabinets comprising materials stored in containers and vessels disposed within the cabinets to thereby ensure that such materials are at a desired controlled or set temperature to facilitate effective use of the material in semiconductor fabrication processing.

### SUMMARY

Example thermal management systems and devices are disclosed herein for use with cabinets comprising materials used in semiconductor fabrication processes. In an example, such cabinets comprise a housing comprising a front panel, a rear panel, a top panel, a bottom panel, and side panels. There is an internal storage space disposed in the cabinet housing for accommodating placement of a storage vessel therein, wherein the storage vessel or container is configured to accommodate placement of a gas, solid, or liquid source material therein that is used in semiconductor fabrication. In an example, the storage vessel is maintained at set temperature. In an example, a thermal insulating material is disposed on a surface of one or more of the housing panels. The thermal insulating material is positioned to reduce transfer of thermal energy from a source external from and adjacent the cabinet into the cabinet internal storage space and to the storage vessel. In an example, the thermal insulating material is positioned at a location that eliminates or mitigates the external thermal energy from influencing the temperature of the storage vessel. In an example, the thermal insulating material is disposed along an outside surface of the one or more housing panels. In an example, the thermal insulating material may be provided as a non-preformed material in the form of a coating, or may be provided in the form of a preformed material in the form of a sheet or panel. In an example, the thermally insulating material has a uniform thickness. In an example, the thermally insulating material is disposed on at least two or more panels of the cabinet.

In an example, an assembly of two or more cabinets may exist that are positioned adjacent one another. In an example, thermal management between one or more of the cabinets may be provided in the form of an air-insulation gap between adjacent outside surfaces of adjacent cabinets. In an example, the air-insulation gap may be at least about 5 mm, and at least about 10 mm. In an example, the cabinets may comprise the thermal insulating material as disclosed above that is disposed on one or more surfaces, e.g., outside surfaces, of one or more of the cabinets for the purpose of eliminating or mitigating an influence of an external thermal condition on a set temperature of a material stored within one or more of the cabinets.

In an example, a method for reducing, mitigating, or eliminating an influence of thermal condition external to a cabinet used for semiconductor fabrication and placed near an external thermal source comprises applying a thermal insulating material to a surface of the cabinet such that the thermal insulating material is interposed between the cabinet surface and the external thermal energy source. In an example, the step of applying may comprise applying a non-preformed material onto the surface of the cabinet to thereby form a layer of the thermal insulating material. In an example, the step of applying may comprise attaching a preformed sheet or panel of the thermal insulating material to the surface of the cabinet. In an example, the method may include providing an air-insulation gap between one or more surfaces of the cabinet and the external thermal source, wherein the one or more surfaces of the cabinet may include the thermally insulating material.

Thermal management systems, devices, and methods disclosed herein are specially configured to reduce, mitigate, or eliminate an influence that an external thermal condition produced by an external thermal source may have on a set temperature of a material stored in a vessel disposed inside a cabinet (wherein the material stored in the vessel is used during semiconductor fabrication processing), thereby ensuring that the material is at a desired proper temperature for effective use during semiconductor fabrication processing.

### BRIEF DESCRIPTION OF THE DRAWINGS

These and other features and advantages of thermal management systems and devices for cabinets used in semiconductor fabrication processing as disclosed herein will be appreciated as the same becomes better understood by reference to the following detailed description when considered in connection with the accompanying drawings where:

FIG. 1 is a front view of three cabinets comprising thermal management systems and devices as disclosed herein;

FIG. 2 is a front view of one cabinet of FIG. 1 showing a material container or vessel disposed therein;

FIG. 3 representatively illustrates a front view of three cabinets comprising thermal management systems and devices as disclosed herein subjected to external thermal conditions in the form of radiation and conduction;

FIG. 4 representatively illustrates a front view of three cabinets comprising thermal management systems and devices as disclosed herein subjected to external thermal conditions in the form of radiation and conduction, and also subjected to external thermal conditions from within an adjacent a cabinet;

FIG. 5 representatively illustrates a perspective front view of an assembly of two cabinets comprising thermal management systems and devices as disclosed herein;

FIG. 6A representatively illustrates a perspective first front view of an assembly of three cabinets comprising thermal management systems and devices as disclosed herein; and

FIG. 6B representatively illustrates a perspective second front view of the assembly of the three cabinets of FIG. 6A comprising thermal management systems and devices as disclosed herein.

### DESCRIPTION

Thermal management systems and devices for cabinets used in semiconductor fabrication processing as disclose herein are generally configured to provide an improved degree of thermal protection, to materials stored inside of the cabinets within one or more containers or vessels, from the influence of thermal conditions external to the cabinet. In an example, the systems or devices may be in the form of a thermal insulating material positioned along one or more desired surfaces of the cabinet adjacent to the external thermal condition, which may be in the form of radiation, conduction, or convection. In an example, the thermal insulating material may be air where the cabinet is positioned a distance from an external thermal condition source, and/or may be a material having thermal insulating properties that may be attached or otherwise applied to the cabinet.

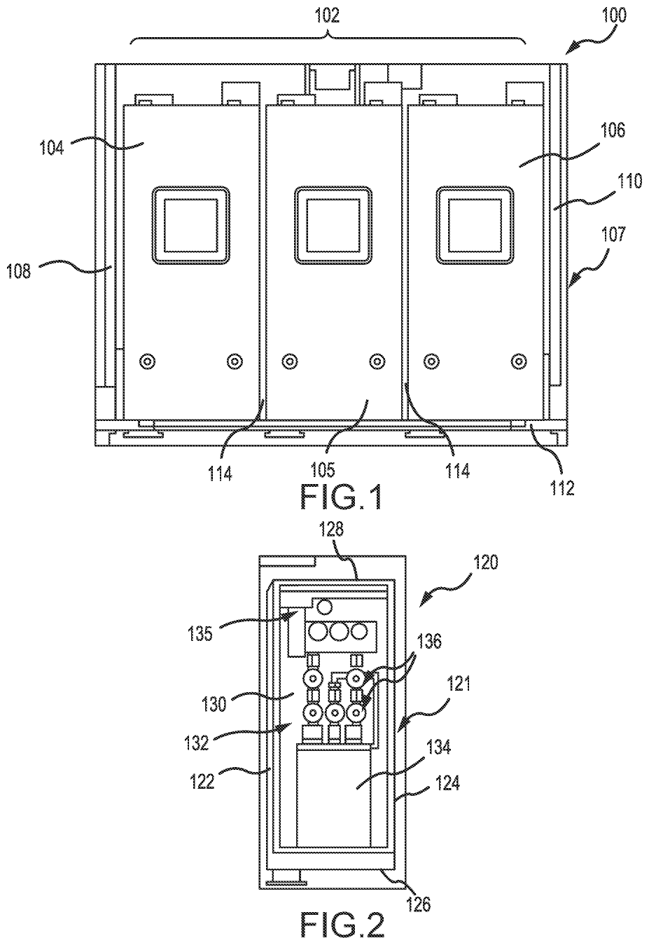

FIG. 1 shows an assembly 100 comprising a number of cabinets 102 positioned adjacent one another, which cabinets are used to store one or more materials therein used during semiconductor fabrication processing. In an example illustrated, the assembly 100 comprises three cabinets 104, 105, 106 that are positioned adjacent one another and arranged in series with a center cabinet 105 and end or outer cabinets 104 and 106 placed on each opposed side of the center cabinet. In an example, the cabinets 102 are disposed in an enclosure 107 having sides surfaces 108 and 110 and a bottom structure 112. In an example, the end cabinets 104 and 106 are positioned a distance apart from adjacent opposed side surfaces of the center cabinet 105 so as to provide an air-insulation gap 114 therebetween, operating to mitigate unwanted transfer of external thermal energy between the center cabinet 105 and the outer cabinets 104 and 106. In an example, in addition to or in place of the air-insulation gap 114, a thermal insulating material may be interposed between the opposed side surfaces of the center cabinet 105 and the outer cabinets 104 and 106, and/or between the side surfaces of the end cabinets 104 and 106 and opposed respective side surfaces 108 and 110 of the enclosure.

The form, type, and placement location of such thermal insulation between the cabinets may depend on such factors as the particular temperatures of the materials disposed within the cabinets. For example, if a material stored in one of the cabinets is maintained at a temperature that is greater (e.g., by more than about 30° C.) than a material stored in an adjacent container, then the use of thermal insulation would be desired and the type of insulation would depend on the extent of the temperature difference. For example, if the temperature difference is sufficiently high (e.g., greater than about 50° C.) then the use of an air-insulation gap may not be sufficient and use of a thermal insulating material applied to one or more surfaces of a cabinet may be desired. In an example, where an air-insulation gap is useful to address the external thermal condition, the air-insulation gap may be greater than about 5 mm, be from about 5 to 100 mm, from about 8 to 20 mm, or may be greater than 100 millimeters depending on the particular cabinet spacing constraints. It is to be understood that the particular size of the air-insulation gap may vary depending on a variety of difference factors, which variation is intended to be within the scope of thermal management systems and devices as disclosed herein.

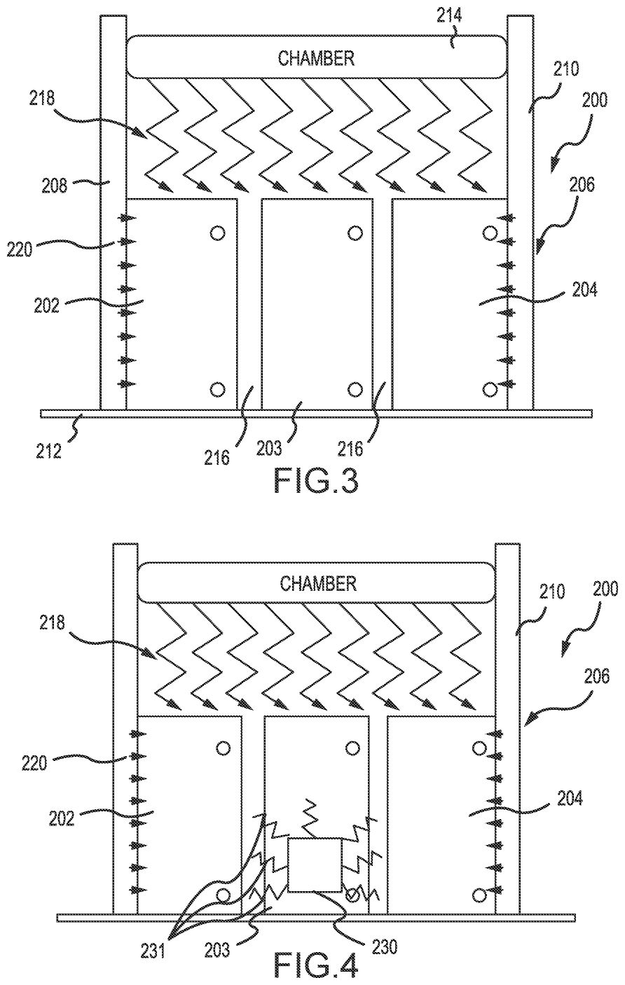

In the example illustrated in FIG. 1, the cabinets 102 are configured comprising a thermal insulating material that is disposed along one or more of the outside surfaces of one or more of the cabinets. In an example, the thermal insulating material is disposed along an outer back surface and an outer top surface of the cabinets (as better described below with reference to FIGS. 3 to 6B). The particular placement position of the thermal insulating material in this example is due to the location of external thermal sources that produce an external thermal condition along the back and top of the cabinets. While a particular placement position of the thermal insulating material for one example has been disclosed, it is to be understood that other thermal insulating material placement positions on the cabinets, e.g., depending on the location of one or more external thermal sources and related external thermal conditions, are understood to be within the scope of thermal management systems and devices as disclosed herein.

Example thermal insulating materials suitable for use as disclosed herein include non-preformed materials that can be applied as a coating by spray, brush or other means to form a thermal insulating layer on the surface of the cabinet. Examples of such non-preformed materials suitable for forming a thermal insulating coating layer include fluoropolymeric materials such as perfluoroalkoxy (PFA), polytetrafluoroethylene (PTFE), and the like; and other polymeric materials having thermal insulating properties such as polyoxymethylene (POM), and the like. Suitable thermal insulating materials also include those that are preformed and provided in the form of a sheet or plate of material that is attached mechanically or by adhesive bond or the like to the surface of the cabinet. Examples of such preformed thermal insulating material include silicones, such as silicone-rubber and the like, that may or may not be in the form of a foam, e.g., an open-pore foam. While a few particular examples of materials useful for forming thermal insulating materials have been described, it is to be understood that other materials having thermal insulating properties may be used to form thermal insulating materials and all such other materials are understood to be within the scope of systems and devices as disclosed herein. The particular thickness of the thermal insulating material can and will vary depending on such factors as the type of thermal insulating material used, the proximity of the external thermal source to the cabinet, and the extent of the external thermal energy that is emitted from the external thermal source. In an example, the thermal insulating material may have a thickness of from about 0.5 mm to 100 mm, from about 5 mm to 50 mm, and from about 10 to 30 mm.

FIG. 2 shows an example cabinet 120 such as one illustrated in FIG. 1, comprising a housing 121 with a front panel or door (shown in FIG. 1) removed from the cabinet to show the contents inside of the cabinet 120. The cabinet housing 121 may be made from a structurally rigid material that is capable of withstanding elevated temperatures without degrading, such as a metallic material or the like. The cabinet housing 121 includes opposed side walls or panels 122 and 124 that each extend from a bottom panel or base 126 of the cabinet housing to a top panel or roof 128 of the cabinet housing 121. The cabinet includes a door (shown in FIG. 1) that covers the front of the cabinet housing and that may be removable or that may be configured to open and close using a hinge assembly or the like. The cabinet housing 121 also includes a back wall or panel 130 that is interposed between the two side walls 122 and 124 and that extends from the base 126 to the roof 128. In an example, the different structural walls, door, base, and roof are all preferably made from the same structurally rigid type of material, such as a metallic material and the like.

The cabinet 120 is sized to accommodate desired contents within an inside space 132. In an example, a storage container or vessel 134 for accommodating a volume of gas, liquid, or solid during the semiconductor fabrication process is disposed in the inside space 132, wherein the container or vessel may be configured, e.g., making use of heating jackets and the like, to facilitate heating of the material that is disposed therein to a controlled or set temperature. In an example, heating control equipment 135 may be disposed inside of the cabinet inside space 132 to facilitate maintaining the contents of the container or vessel 134 at a desired set temperature. Fluid handling elements 136 such as pumps, valves, pipes, and the like may also be disposed inside the cabinet inside space 132 to enable transport of the contents from the container or vessel 134 to a location outside of the cabinet, e.g., to a reactor or reaction chamber used for semiconductor fabrication processing. This is but one example embodiment of a cabinet and its contents as used for semiconductor fabrication processing provided for purpose of reference. Cabinets and the contents of such cabinets as used for semiconductor fabrication processing may be configured differently than as disclosed and illustrated, and thermal management systems and devices as disclosed herein are understood to be used in conjunction with all such differently configured cabinets and contents for the purpose of eliminating or mitigating the influence that external thermal conditions may have on the contents of such cabinets.

FIG. 3 shows an example assembly 200 of cabinets, in this example three cabinets 202, 203, and 204 that are disposed in an enclosure 206. The cabinets in this example comprise gas, liquid, or solid material stored in a container or vessel disposed inside of the cabinets, wherein the material in the container or vessel is stored at a desired set temperature for use in semiconductor fabricator processing. The enclosure 206 comprises opposed side walls 208 and 210 that each extend vertically from a base or floor 212 that may be separate from or part of the enclosure 206. A reaction chamber 214 used for semiconductor fabrication processing is positioned a distance above the cabinets in the enclosure 206. In this example, end cabinets 202 and 204 are positioned with side walls against respective side walls 208 and 210 of the enclosure. The center cabinet 203 is located such that there is an air-insulation gap 216 between the side surfaces of the center cabinet 203 and adjacent side surfaces of the end cabinets 202 and 204.

FIG. 3 illustrates example external thermal sources that produce thermal conditions that may influence the temperature inside of the cabinets. The reaction chamber 214 emits radiant thermal energy 218 external from the cabinets that is transmitted to all three cabinets 202, 204, and 206. Additionally, the reaction chamber 214 emits conductive thermal energy to the enclosure side walls 208 and 210, which thermal energy is conductively transmitted 220 to the adjacent side walls of the end cabinets 202 and 204. Accordingly, in this example, all three cabinets are exposed to external thermal energy from the reaction chamber 214 in the form of the radiant thermal energy 218, and the two end cabinets 202 and 204 are exposed to external energy from the reaction in the form of the conductive thermal energy 220. In such an example, in an effort to eliminate or mitigate the influence of such external thermal on the contents of the cabinets 200, it may be desired to place the thermally insulating material disclosed above along the outside surface of the tops of the three cabinets (to address the external radiative thermal energy), and along the outside surface of the side walls of the end cabinets 202 and 204 that are adjacent the enclosure side walls 208 and 201. In this example, the air-insulation gap 216 provided by the open space between the side walls of the center cabinet 203 and the side walls of the end cabinets 202 and 204 may be sufficient to eliminate or mitigate the influence of the external thermal radiation and conduction energy generated by the reaction chamber 214. However, thermal insulating material may also be provided along the outside surfaces of the center cabinet 203 side walls and/or the outside surfaces of the end cabinets 202 and 204 adjacent the center cabinet depending on the extent of the external thermal condition being produced by the thermal reactor.

FIG. 4 shows an example assembly of cabinets 200, e.g., cabinets 202, 203, and 204, as placed in an enclosure 206 that is similar to that described above and illustrated in FIG. 3. A difference here is that one of the cabinets, e.g., the center cabinet 203, contains a container or vessel or other element 230 disposed therein that is operated at an elevated temperature. In this example, the center cabinet element 230 is operating at an elevated temperature that is greater than the temperature that containers or vessels or other elements stored in one or both of the end cabinets 202 and 204 are operated at. Thus, in this example, the center cabinet 203 is also a source of external thermal energy 231 that is being emitted relative to the end cabinets 202 and 204. So in this example, in addition to the radiant thermal energy 218 produced by the reaction chamber 214 and the conductive thermal energy 220 transmitted by the enclosure 206, the end cabinets 202 and 204 are subjected to convective or radiant energy 231 emitted from the center cabinet 203. In such example, in addition to the use of the thermal insulating material as discussed above for FIG. 3, it may be desired to provide the thermal insulating material along the outer surfaces of the side walls of the end cabinets 202 and 204 that are adjacent the center cabinet 203, and possibly also along the outer surfaces of the center cabinet 203 side walls, to thereby eliminate or mitigate thermal energy provided by the center cabinet 203 from influencing the temperature of the contents inside of the end cabinets 202 and 204. This example is useful for illustrating a situation where the source of the external thermal condition needing to be thermally managed, by systems as devices as disclosed herein, may be due to different temperatures of contents being stored in adjacent cabinets, i.e., the temperature differential of contents inside adjacent cabinets. Thus, thermal management systems and devices as disclosed herein are configured to address such situations through the use of the thermal insulation material and the strategic placement position of the same on the cabinet surfaces as useful to address all potential sources of external thermal energy.

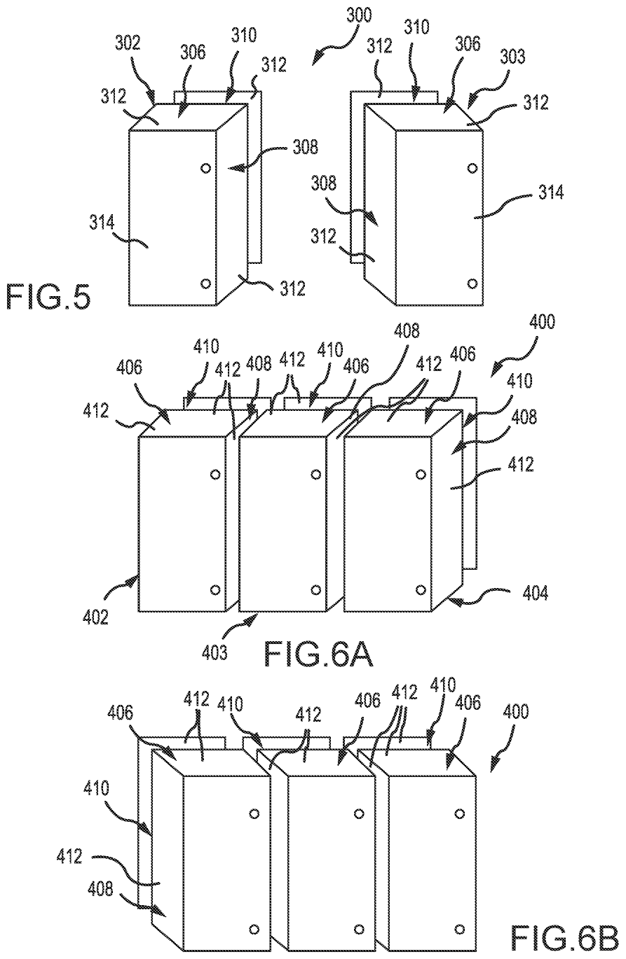

FIG. 5 illustrates an assembly 300 of two cabinets 302 and 303 of the type described above that are configured to accommodate a container or vessel therein for storing a liquid or fluid at a particular temperature used for semiconductor fabrication processing. In an example, the cabinets 302 and 303 have top surfaces 306, side surfaces 308, and back surfaces 310 each having the thermal insulating material 312 disposed therein, e.g., attached or coated as disclosed above. In an example, the cabinet doors 314 may or may not include the thermal insulating material. In the example illustrated, the cabinet doors 314 do not include the thermal insulating material. In this example, the cabinet side surfaces that are not adjacent one another may or may not include the thermal insulating material disposed thereon depending on the particular placement environment and whether there is any external thermal energy presence adjacent such surfaces.

FIGS. 6A and 6B show different perspective views of an assembly 400 of three cabinets 402, 403, and 404 of the type described above that are configured to accommodate a container or vessel therein for storing a liquid or fluid at a particular temperature used for semiconductor fabrication processing. In an example, the cabinets 402, 403, and 404 have top surfaces 406, side surfaces 408, and back surfaces 410 each having the thermal insulating material 412 disposed therein, e.g., attached or coated as disclosed above. In an example, the cabinet doors 414 may or may not include the thermal insulating material. In the example illustrated, the cabinet doors 414 do not include the thermal insulating material.

Although but a few example embodiments of thermal management systems and methods for eliminating or mitigation the influence of external thermal conditions on cabinets as used in semiconductor fabrication processing have been disclosed in detail above, those skilled in the art will readily appreciate that many modifications are possible in the example embodiments without materially departing from the intent and purpose of the example systems and method as disclosed herein. For example, while use of the thermal insulating material has been disclosed as being placed along an outside surface of the cabinets, such thermal insulating material may additionally or alternatively be placed along an inside surface of the cabinets. Also, while the thermal insulating material has been disclosed or illustrated as being placed along a substantial entire surface of one or more walls or panels of cabinets, it is to be understood that the thermal insulating material may be placed along only a partial surface of a wall or panel depending as may be called for by a particular use application. Accordingly, all such modifications of thermal management systems and devices are intended to be included within the scope of this disclosure as defined in the following claims.

What is claimed is:

1. A cabinet used with semiconductor fabrication, the cabinet comprising:
a housing comprising a front panel, a rear panel, a top panel, a bottom panel, and side panels, an internal storage space disposed in the housing for accommodating placement of a storage vessel therein comprising a gas, solid, or liquid source material for use in semiconductor fabrication, wherein the storage vessel is maintained at set temperature; and
a thermal insulating material disposed on a surface of one or more of the housing panels, wherein the insulating material is positioned to reduce a transfer of thermal energy into the cabinet internal storage space and to the storage vessel from a thermal energy source external from and adjacent the cabinet.

2. The cabinet of claim 1, wherein the thermal insulating material is positioned on the one or more housing panels at a location adjacent the external thermal energy source.

3. The cabinet of claim 1, wherein the thermal insulating material is interposed between the external thermal energy source and the storage vessel.

4. The cabinet of claim 1, wherein the thermal insulating material is disposed on an outside surface of the one or more housing panels.

5. The cabinet of claim 1, wherein the thermal insulating material is a coating that is applied to the surface of the one or more housing panels.

6. The cabinet of claim 1, wherein the thermal insulating material is a preformed material that is attached to the surface of the one or more housing panels.

7. The cabinet of claim 5, wherein the thermal insulating material has a uniform thickness.

8. The cabinet of claim 1, wherein the thermal insulating material is disposed on at least two panels of the cabinet.

9. The cabinet of claim 1, wherein the cabinet is positioned adjacent a second cabinet, and wherein an air gap exists between adjacent outside surfaces of the cabinet and second cabinet.

10. An assembly, comprising:
a first cabinet and a second cabinet positioned adjacent one another, wherein each of the first and second cabinets includes an inner storage space for accommodating placement of a storage vessel therein comprising a gas, solid, or liquid source material for use in semiconductor fabrication, wherein the storage vessel is maintained at set temperature, wherein an air gap is provided between adjacent outside surfaces of the first and second cabinets to reduce a transfer of thermal energy from one of the first or second cabinet to the other of the first or second cabinet.

11. The assembly of claim 10, wherein the air gap is at least 5 mm.

12. The assembly of claim 10, wherein the air gap is at least 10 mm.

13. The assembly of claim 10 comprising a thermal insulating material interposed between the adjacent outside surfaces of the first and second cabinets.

14. The assembly of claim 13, wherein the thermal insulating material is disposed on the outside surface of at least one of the first or second cabinet.

15. The assembly of claim 13, wherein the thermal insulating material is selected from the group of non-preformed insulating materials applied as a coating, and preformed insulating materials applied by attachment.

16. A method for maintaining a set temperature of a storage vessel disposed in a cabinet that is positioned adjacent an external thermal energy source used for semiconductor fabrication, wherein the storage vessel comprises a material used for semiconductor fabrication, the method comprising applying a thermal insulating material to a surface of the cabinet positioned adjacent the external thermal energy source.

17. The method of claim 16, wherein during the step of applying, the thermal insulating material is applied to an inner or outside surface of the cabinet at a location on the cabinet that prevents transfer of thermal energy from the external thermal energy source to the storage vessel.

18. The method of claim 16, wherein during the step of applying, the thermal insulating material is applied in the form of a non-preformed material or is applied in the form of a preformed material.

19. The method of claim 16 further comprising the step of providing an air gap between the external thermal energy source and the thermal insulating material.

20. The method of claim 16, wherein the air gap is at least 5 mm.
